(19) United States
(12) Patent Application Publication
(10) Pub. No.: US 2024/0309158 A1
(43) Pub. Date: Sep. 19, 2024

(54) RESIN SHEET FOR PACKAGING ELECTRONIC COMPONENT, AND ELECTRONIC COMPONENT PACKAGING CONTAINER USING SAME

(71) Applicant: DENKA COMPANY LIMITED, Tokyo (JP)

(72) Inventors: Ikuka INODA, Tokyo (JP); Ryosuke YANAKA, Tokyo (JP); Takeshi SAITO, Tokyo (JP)

(73) Assignee: DENKA COMPANY LIMITED, Tokyo (JP)

(21) Appl. No.: 18/271,597

(22) PCT Filed: Feb. 1, 2022
(86) PCT No.: PCT/JP2022/003760

§ 371 Date: Jul. 10, 2023

(30) Foreign Application Priority Data
Mar. 22, 2021 (JP) 2021-047119

(51) Int. Cl. C08J 5/18

(52) U.S. Cl. CPC C08J 5/18; C08J 2325/14; C08J 2409/06

(57) ABSTRACT

A resin sheet for electronic component packaging with transparency, excellent folding endurance, and also excellent low-temperature heat sealing property, and an electronic component packaging container using the resin sheet. A resin sheet for electronic component packaging, the resin sheet composed of a rubber-modified aromatic vinyl-based copolymer resin that includes rubber-type polymers (Y) as dispersed particles in a continuous matrix resin (X), and that satisfies (1) and (2): (1) the continuous matrix resin (X) is a copolymer of 53-63 mass % of one or more aromatic vinyl-based compounds (x1) and 37-47 mass % of one or more (meth)acrylic acid alkyl esters (x2); and (2) the ratio of the rubber-type polymers (Y) to the total mass of the rubber-modified aromatic vinyl-based copolymer resin is 5 mass % or more and less than 10 mass %.

### TECHNICAL FIELD

The present invention relates to a resin sheet for packaging electronic component, and an electronic component packaging container using the resin sheet.

### BACKGROUND

For electronic component packaging containers such as IC magazines, IC carrier tapes, etc., hard polyvinyl chloride (PVC) has been conventionally used due to its excellent physical properties such as transparency, impact resistance, rigidity, and surface hardness. However, there is a demand for an alternative material for PVC due to acidic corrosive gases generated during waste incineration, generation of toxic substances, etc. As an alternative material to overcome these drawbacks, blended resins including at least one resin selected from polystyrene and styrene-(meth)acrylic acid ester copolymers, and a styrene-butadiene block copolymer are known (e.g. Patent Document 1, etc.). However, with these blended resins, it is difficult to achieve both rigidity and impact resistance, which are required for electronic component packaging containers. That is, this blend-based resin has an inverse relationship in which increasing rigidity reduces impact resistance, and increasing impact resistance reduces rigidity, so it is difficult to say that it is a well-balanced material that can simultaneously achieve rigidity and impact resistance which are demanded for electronic component packaging containers. In addition, other known alternative materials for PVC include polycarbonate resins, transparent ABS resins, and the like, but have high costs and are impractical as low-cost PVC alternative materials.

Patent Document 2 proposes a rubber-modified styrene-based resin composition from which a transparent molded body for electronic component packaging with high strength, excellent transparency and rigidity, and high surface hardness can be obtained. Patent Document 2 describes a transparent molded body for electronic component packaging formed from a rubber-modified styrene-based resin composition, wherein the rubber-modified styrene-based resin composition is consisted of: a rubber-modified styrene-based resin obtained by polymerizing a mixed solution consisting of styrene, a (meth)acrylic acid alkyl ester, and a butadiene-based rubber polymer; and a terpene-based resin or a terpene-based hydrogenated resin. However, molded bodies formed from such a rubber-modified styrene-based resin composition are insufficient in its properties such as strength, transparency, etc., as well as surface hardness.

In contrast therewith, Patent Document 3 proposes a rubber-modified aromatic vinyl-based copolymer resin from which a molded body for electronic component packaging with excellent properties such as strength, transparency, etc. as well as sufficiently high surface hardness can be obtained. Patent Document 3 describes that a transparent molded body for electronic component packaging with high strength, excellent transparency and rigidity, and also high surface hardness can be obtained by profile extrusion molding a resin composition in which a styrene-butadiene block copolymer with a specific structure has been dispersed as a rubber polymer in a mixture of an aromatic vinyl-based compound and a (meth)acrylic acid alkyl ester compound, wherein the styrene-butadiene block copolymer can be graft copolymerized with the above-mentioned mixture and has a particularly strong affinity with the above-mentioned mixture.

### CITATION LIST

### Patent Literature

Patent Document 1: JP H8-12847 A
Patent Document 2: JP H9-301479 A
Patent Document 3: JP 2002-193378 A

### SUMMARY OF INVENTION

### Technical Problem

Meanwhile, in recent years, for electronic component packaging containers, there is also a demand for low-temperature heat sealing properties that can provide a high peel strength in a short sealing time, in view of the high-speed required when filling electronic components. In addition, there is also a demand for balancing physical properties such as folding endurance, moldability, etc., while maintaining a high transparency that allows the contents, i.e., the electronic components to be visible from the outside.

Thus, the objective of the present invention is to provide a resin sheet for electronic component packaging with transparency, excellent folding endurance, and also excellent low-temperature heat sealing property, and an electronic component packaging container using the resin sheet.

### Solution to Problem

As a result of diligently studying the above-mentioned problems, the present inventors discovered, to their surprise, that a resin sheet with excellent transparency, impact resistance, and rigidity, and also with excellent low-temperature heat sealing property can be obtained by a resin sheet composed of a rubber-modified aromatic vinyl-based copolymer resin that includes rubber-type polymers as dispersed particles in a continuous matrix resin formed by copolymerizing an aromatic vinyl-based compound and a (meth)acrylic acid alkyl ester, wherein 53-63 mass % of the aromatic vinyl-based compound and 37-47 mass % of the (meth)acrylic acid alkyl ester are copolymerized, and the rubber-type polymers are configured to be 5 mass % or more and less than 10 mass % with respect to the total mass of the rubber-modified aromatic vinyl-based copolymer resin, thereby completing the present invention.

That is, the present invention has the aspects below.

[1] A resin sheet for electronic component packaging, the resin sheet composed of a rubber-modified aromatic vinyl-based copolymer resin that includes rubber-type polymers (Y) as dispersed particles in a continuous matrix resin (X), and that satisfies (1) and (2) below:
(1) the continuous matrix resin (X) is a copolymer of 53-63 mass % of one or more aromatic vinyl-based compounds (x1) and 37-47 mass % of one or more (meth)acrylic acid alkyl esters (x2); and
(2) the ratio of the rubber-type polymers (Y) with respect to the total mass of the rubber-modified aromatic vinyl-based copolymer resin is 5 mass % or more and less than 10 mass %.

[2] The resin sheet for electronic component packaging of [1], wherein the (meth)acrylic acid alkyl ester (x2) includes methyl methacrylate (x2-1), and a (meth)acrylic acid alkyl ester (x2-2) having a linear or branched alkyl group with 4-8 carbon atoms.

[3] The resin sheet for electronic component packaging of [2], wherein the ratio of the (meth)acrylic acid alkyl ester (x2-2) with respect to the total mass of the (meth)acrylic acid alkyl ester (x2) is 5-50 mass %.

[4] The resin sheet for electronic component packaging of [2] or [3], wherein the (meth)acrylic acid alkyl ester (x2-2) includes butyl acrylate.

[5] An electronic component packaging container formed using the resin sheet for electronic component packaging of any one of [1] to [4].

[6] The electronic component packaging container of [5], wherein the electronic component packaging container is a carrier tape.

[7] The electronic component packaging container of [5], wherein the electronic component packaging container is a tray.

[8] An electronic component packaging body including the electronic component packaging container of any one of [5] to [7].

### Effects of Invention

According to the present invention, it is possible to provide a resin sheet for electronic component packaging with transparency, excellent folding endurance, and also excellent low-temperature heat sealing property, and an electronic component packaging container using the resin sheet.

### DESCRIPTION OF EMBODIMENTS

The present invention shall be explained in more detail below, but the present invention is not limited to the aspects below.

Note that herein, “- (hyphen)” with regard to numerical range means “or more” and “or less.” For example, “5-10 mass %” means “5 mass % or more and 10 mass % or less.”

### [Resin Sheet for Electronic Component Packaging]

The resin sheet for electronic component packaging according to the present invention (hereinafter sometimes simply referred to as “resin sheet”) is composed of a rubber-modified aromatic vinyl-based copolymer resin that includes rubber-type polymers (Y) as dispersed particles in a continuous matrix resin (X), and that satisfies (1) and (2) below.

(1) The continuous matrix resin (X) is a copolymer of 53-63 mass % of one or more aromatic vinyl-based compounds (x1) and 37-47 mass % of one or more (meth)acrylic acid alkyl esters (x2); and

(2) the ratio of the rubber-type polymers (Y) with respect to the total mass of the rubber-modified aromatic vinyl-based copolymer resin is 5 mass % or more and less than 10 mass %.

The resin sheet for electronic component packaging according to the present invention, which is composed of a rubber-modified aromatic vinyl-based copolymer resin having such a characteristic composition, has transparency, excellent folding endurance, and also excellent low-temperature heat sealing property.

### <Rubber-Modified Aromatic Vinyl-Based Copolymer Resin>

The rubber-modified aromatic vinyl-based copolymer resin according to the present invention (hereinafter, simply referred to as “copolymer resin”) is characterized by including rubber-type polymers (Y) as dispersed particles in a continuous matrix resin (X) and by satisfying (1) and (2) below.

(1) The continuous matrix resin (X) is a copolymer of 53-63 mass % of one or more aromatic vinyl-based compounds (x1) and 37-47 mass % of one or more (meth)acrylic acid alkyl esters (x2); and

(2) the ratio of the rubber-type polymers (Y) with respect to the total mass of the rubber-modified aromatic vinyl-based copolymer resin is 5 mass % or more and less than 10 mass %.

By satisfying (1) and (2) above, a resin sheet with excellent low-temperature heat sealing property, transparency, and folding endurance can be obtained.

### (Continuous Matrix Resin (X))

The continuous matrix resin (X) is a resin component that forms a continuous phase in a copolymer resin. The continuous matrix resin (X) is a copolymer of one or more aromatic vinyl-based compounds (x1) (hereinafter, sometimes referred to as “(x1) component”) and one or more (meth)acrylic acid alkyl esters (x2) (hereinafter, sometimes referred to as “(x2) component”). Specifically, the continuous matrix resin (X) is obtained by copolymerizing 53-63 mass % of the (x1) component and 37-47 of mass % of the (x2) component with respect to the total mass of the continuous matrix resin (X).

(Aromatic Vinyl-Based Compound (x1))

As the aromatic vinyl-based compound (x1), styrene-based compounds conventionally used in rubber-modified styrene-based resins, for example such as styrene; α-alkyl substituted styrene such as α-methylstyrene and α-methyl-p-methylstyrene; nucleus alkyl substituted styrene such as α-methylstyrene, m-methylstyrene, p-methylstyrene, 2,4-dimethylstyrene, ethylstyrene, and p-tert-butylstyrene; nucleus halogenated styrene such as o-chlorostyrene, m-chlorostyrene, p-chlorostyrene, p-bromostyrene, 2-methyl-1,4-chlorostyrene, and 2,4-dibromostyrene; vinylnaphthalene; and the like may be used alone or as a combination of two or more. Of these, styrene is preferably used.

The ratio of the (x1) component in the continuous matrix resin (X) is 53-63 mass %, preferably 53.5-62.5 mass %, more preferably 54-61 mass %, and particularly preferably 54-60 mass % with respect to the total mass of the continuous matrix resin (X). By setting the ratio of the (x1) component within the above range, the ratio of the (x2) component in the continuous matrix resin (X) can be adjusted to 37-47 mass %, making it possible to obtain a resin sheet with excellent low-temperature heat sealing property. Particularly preferred is a copolymer resin including, as the (x1) component, 53-63 mass % and preferably 53.5-62.5 mass % of styrene with respect to the total mass of the continuous matrix resin (X). Note that the ratio of the (x1) component in the (X) component indicates the ratio of the (x1) component with respect to the total amount (100 mass %) of all of the monomers constituting the (X) component. Setting the ratio of the (x1) component so as to be 53-63 mass % can be achieved, for example, by adjusting the preparation ratio of the monomers. The same also applies to the ratio of the (x2) component in the (X) component, which is described below.

The ratio of the (x1) component in the copolymer resin is preferably 48.0-57.0 mass %, more preferably 49.5-55.0 mass %, and particularly preferably 50.5-54.0 mass %, with respect to the total mass of the copolymer resin. When the ratio of the (x1) component in the copolymer resin is within the above range, it is easier to obtain a resin sheet with a more excellent low-temperature heat sealing property. Note that the ratio of the (x1) component in the copolymer resin is a value calculated from the following formula (1).

$$[ ( x 1 ) / ( X + Y ) ] \times 100 \qquad ( 1 )$$

In formula (1), x1 is the total preparation amount of all the monomers constituting the (x1) component, and X is a value obtained by multiplying a polymerization rate (%) by the total preparation amount of all of the monomers constituting the (X) component, and Y is the preparation amount of all of the rubber-type polymers constituting the (Y) component.

((Meth)acrylic Acid Alkyl Ester (x2))

In the copolymer resin according to the present invention, (meth)acrylic acid alkyl ester means methacrylic acid alkyl esters and acrylic acid alkyl esters.

The (x2) component includes, for example, (meth)acrylic acid alkyl esters having a linear or branched alkyl group with 1 to 18 carbon atoms. Specifically, the (x2) component include methyl methacrylate, ethyl methacrylate, butyl methacrylate, lauryl methacrylate, tridecyl methacrylate, palmitic methacrylate, pentadecyl methacrylate, stearyl methacrylate, methyl acrylate, ethyl acrylate, butyl acrylate, lauryl acrylate, tridecyl acrylate, palmitic acrylate, pentadecyl acrylate, stearyl acrylate, and the like. The foregoing may be used alone or as a combination of two or more.

The ratio of the (x2) component in the continuous matrix resin (X) is 37-47 mass %, preferably 37.5-46.5 mass %, more preferably 39-46 mass %, and particularly preferably 40-45 mass %, with respect to the total mass of the continuous matrix resin (X). By setting the ratio of the (x2) component within the above range, the ratio of the (x1) component in the continuous matrix resin (X) can be adjusted to 53-63 mass %, making it possible to obtain a resin sheet with excellent low-temperature heat sealing property.

The ratio of the (x2) component in the copolymer resin is preferably 33-44 mass % and more preferably 35-44 mass % with respect to the total mass of the copolymer resin. Making the ratio of the (x2) component in the copolymer resin within the above range makes it easier to obtain a resin sheet with excellent heat sealing property at lower temperatures. Note that when methyl methacrylate and butyl acrylate described below are included as the (x2) component, the ratio of the (x2) component in the copolymer resin may be within a range of 37-43 mass % with respect to the total mass of the copolymer resin.

The ratio of the (x2) component in the copolymer resin is calculated from the following formula (2).

$$[ ( x 2 ) / ( X + Y ) ] \times 100 \qquad ( 2 )$$

In formula (2), x2 is the total preparation amount of all of the monomers constituting the (x2) component, and X is a value obtained by multiplying a polymerization rate (%) by the total preparation amount of all of the monomers constituting the (X) component, and Y is the total preparation amount of all of the rubber-type polymers constituting the (Y) component.

The (x2) component preferably includes, among the above-mentioned (meth)acrylic acid alkyl esters, methyl methacrylate (x2-1) (hereinafter, sometimes referred to as the “(x2-1) component”), and a (meth)acrylic acid alkyl ester (x2-2) having a linear or branched alkyl group with 4-8 carbon atoms (hereinafter, sometimes referred to as the “(x2-2) component”).

Examples of the (x2-2) component include (meth)butyl acrylate, (meth)2-ethylhexyl acrylate, and the like.

Among the (meth)acrylic acid alkyl esters, methyl methacrylate (MMA), (meth)acrylic acid alkyl ester having an alkyl group with 4-8 carbon atoms, etc. are inclined to have a low Tg. Combining monomers of (meth)acrylic acid alkyl ester having a low Tg with one another in this way makes it easier to soften resins at low temperatures and to obtain resin sheets with excellent heat-sealing properties at low temperatures.

As the (x2-2) component, an acrylic acid alkyl ester having a linear or branched alkyl group with 4-8 carbon atoms is preferred, butyl acrylate and 2-ethylhexyl acrylate are more preferred, and butyl acrylate is particularly preferred. In addition, the (x2) component is most preferably a mixture of the (x2-1) component and butyl acrylate. Combining the (x2-1) component with butyl acrylate lowers the Tg of the continuous matrix resin (X), improves the low-temperature heat sealing property, and causes the transparency, the folding endurance, etc. to be less likely to deteriorate.

The ratio of the (x2-2) component in the (x2) component is preferably 5-50 mass %, more preferably 10-40 mass %, still more preferably 10-30 mass %, and particularly preferably 10-20 mass %, with respect to the total mass of the (x2) component. When the ratio of the (x2-2) component in the (x2) component is within the above range, the heat sealing property at low temperature is likely to be good, and the balance of transparency, folding endurance, etc. is also likely to be good. Note that from the viewpoint that the heat sealing property is likely to be better at lower temperatures, the ratio of the (x2-2) component with respect to the total mass of the (x2) component may be within a range of 13-18 mass %.

Herein, the ratio of the (x2-2) component in the (x2) component indicates the ratio of the (x2-2) component with respect to the total amount (100 mass %) of the (meth)acrylic acid alkyl ester constituting the (x2) component.

In one aspect, when the (x2) component is a mixture of the (x2-1) component and the (x2-2) component, and the (x2-2) component is butyl acrylate, the ratio of MMA and butyl acrylate (MMA/butyl acrylate) is, from the viewpoint that the heat sealing property is likely to be better at lower temperatures, preferably between 1 and 7, more preferably between 3 and 7, and particularly preferably between 4 and 6. Making the ratio of MMA and butyl acrylate within the above range makes it easier to both maintain sheet strength and keep the Tg of the resin sheet lower. This makes it easier to obtain a resin sheet that has both heat sealing property at low temperatures and physical properties such as folding endurance, etc.

The continuous matrix resin (X) may include the (x1) component and monomers other than the (x2) component (other monomers). The other monomers are compounds that can copolymerize with the (x1) component and the (x2) component, and include, for example, vinyl cyanides such as acrylonitrile, methacrylonitrile, fumaronitrile, maleonitrile, and α-chloroacrylonitrile; methacrylic acid; acrylic acid; maleimides such as maleic anhydride and phenylmaleimide; vinyl acetate; divinylbenzene, and the like. The foregoing may be used alone or as a combination of two or more. Note that from the viewpoint of maintaining a balance of various properties such as image clarity, folding endurance, etc., as well as making it easy to obtain a resin sheet with excellent low-temperature heat sealing property, it is particularly preferred that the continuous matrix resin (X) consists only of the (x1) component and the (x2) component.

### (Rubber-Like Polymers (Y))

The copolymer resin according to the present invention includes 5 mass % or more and less than 10 mass % of rubber-type polymers (Y) with respect to the total mass of the copolymer resin.

For electronic component packaging containers, high transparency, which allows packaged electronic components to be visible from the outside, is required. Conventional resin sheets composed of rubber-modified aromatic vinyl-based copolymer resins have a difficulty in reducing the blended amount of rubber components in terms of sheet strength (impact resistance and rigidity), so about 12 mass % of rubber components need to be blended. Therefore, it is difficult to reduce the blended amount of the rubber components to obtain a resin sheet which has both higher transparency (image clarity) and high sheet strength. The present inventors found that controlling the blending ratio of the (x1) component and the (x2) component constituting the continuous matrix resin (X) so as to be within a certain range makes it easier to obtain a resin sheet with sufficient sheet strength even when the blending amount of the rubber-type polymers (Y) is reduced. Moreover, the inventors also found, to their surprise, that combining the (x1) component and the (x2) component within the above-mentioned specific range makes it easier to soften resins and to obtain a resin sheet with excellent heat-sealing property at lower temperatures. As mentioned above, since the copolymer resin according to the present invention has a rubber-type polymer (Y) ratio of 5 mass % or more and less than 10 mass %, the transparency thereof is also good.

The rubber-type polymers (Y) are preferably copolymers of styrene and butadiene. The ratio of the rubber-type polymers (Y) in the copolymer resin is preferably 5-9 mass %, more preferably 5.5-8.5 mass %, and particularly preferably 5.5-8.0, with respect to the total mass of the copolymer resin.

Note that a value calculated from the following formula (3) may be used as the blending amount of the rubber-type polymers (Y) in the copolymer resin.

$$[ ( Y ) / ( X + Y ) ] \times 100 \qquad ( 3 )$$

In formula (3), Y is the total preparation amount of all of the rubber-type polymers (Y), and X is a value obtained by multiplying a polymerization rate (%) by the total preparation amount of all of the monomers constituting the (X) component.

The rubber-type polymers (Y) included in the copolymer resin according to the present invention are preferably styrene-butadiene copolymers (SBR). In addition, the styrene concentration in the SBR is preferably 10-50 mass %, more preferably 10-45 mass %, and still more preferably 15-40 mass %, with respect to the total mass of the SBR. When the styrene concertation is within the above range, the difference in refractive indexes between the matrix resin (X) and the rubber-type polymers (Y) is reduced, which makes the transparency more likely to be good.

### <Manufacturing Method of Rubber-Modified Aromatic Vinyl-Based Copolymer Resin>

The copolymer resin according to the present invention can be used to obtain a copolymer resin that includes rubber-type polymers (Y) as dispersed particles in a continuous matrix resin (X) by, for example, polymerizing a raw material mixture including an (x1) component and an (x2) component in the presence of the rubber-type polymers (Y).

The ratio of the (x1) component and the (x2) component in the raw material mixture can be adjusted such that the (x1) component in the continuous matrix resin (X) is 53-63 mass % and the (x2) component is 37-47 mass %.

The rubber-type polymers (Y) may be commercially available products or manufactured by living anionic polymerization, etc.

As a commercially available product, “ASAPRENE®”, etc. manufactured by Asahi Kasei Corporation can be used.

When manufacturing the rubber-type polymers (Y), a method such as, for example, living anionic polymerizing a monomer mixture including styrene and butadiene in the presence of an organic lithium catalyst in a hydrocarbon solvent may be adopted. Specifically, the method described in JP 2002-193378 A, etc. can be adopted.

The above-mentioned raw material mixture can contain organic solvents as needed. Examples of the organic solvents include benzene, toluene, xylene, ethylbenzene, acetone, isopropyl benzene, methyl ethyl ketone, methyl isobutyl ketone, dimethylformamide, and the like. The foregoing may be used alone or as a combination of two or more. Of these, toluene and ethylbenzene are preferred. Using the organic solvents makes it easier to control the monomer concentration and the polymer concentration in the polymerization liquid and to control the polymerization reaction. When used, an organic solvent can be in a range of 5-50 parts by mass with respect to the total amount (100 parts by mass) of the raw material mixture for manufacturing the copolymer resin. Being within a range of 5-10 parts by mass is more preferable.

Moreover, other solvents, such as aliphatic hydrocarbons and dialkyl ketones can be used in combination with aromatic hydrocarbons to the extent that the solubility of the rubber-type polymers (Y) is not impaired.

The raw material mixture may include polymerization initiators. As a polymerization initiator, organic peroxides are preferably used.

Examples of the organic peroxides include peroxy ketals such as 2,2-bis(t-butylperoxy)butane, 2,2-bis(t-butylperoxy)octane, 1,1-bis(t-butylperoxy)3,3,5-trimethylcyclohexane, and n-butyl-4,4-bis(t-butylperoxy)valerate; dialkyl peroxides such as di-t-butyl peroxide, t-butyl cumyl peroxide, dicumyl peroxide, α,α′-bis(t-butylperoxyisopropyl)benzene, 2,5-dimethyl-2,5-di(t-butylperoxy)hexane, and 2,5-dimethyl-2,5-bis(t-butylperoxy)hexyne-3; diacyl peroxides such as acetyl peroxide, isobutyryl peroxide, octanoyl peroxide, decanoyl peroxide, lauroyl peroxide, 3,5,5-trimethyl hexanoyl peroxide, benzoyl peroxide, 2,4-dichlorobenzoyl peroxide, and m-toluoyl peroxide; peroxy carbonates such as di-isopropyl peroxydicarbonate, di-2-ethylhexyl peroxydicarbonate, di-n-propyl peroxydicarbonate, di-3-methoxybutyl peroxydicarbonate, di-2-ethoxyethyl peroxydicarbonate, di-methoxyisopropyl peroxydicarbonate, di(3-methyl-3-methoxybutyl)peroxydicarbonate, and bis(4-t-butylcyclohexyl)peroxydicarbonate; peroxy esters such as t-butyl peroxyacetate, t-butyl peroxyisobutyrate, t-butyl peroxypiperate, t-butyl peroxyneodecanoate, cumyl peroxyneodecanoate, t-butylperoxy-2-ethylhexanoate, t-butylperoxy-3,5,5-trimethylhexanoate, t-butyl peroxy laurate, t-butyl peroxy benzoate, di-t-butyl diperoxy isophthalate, 2,5-dimethyl-2,5-di(benzoylperoxy)hexane, and t-butyl peroxy isopropyl carbonate; ketone peroxides such as acetylacetone peroxide, methyl ethyl ketone peroxide, cyclohexanone peroxide, 3,3,5-trimethylcyclohexanone peroxide, and methylcyclohexanone peroxide; hydroperoxides such as t-butyl hydroperoxide, cumene hydroperoxide, di-isopropylbenzene hydroperoxide, p-menthane hydroperoxide, 2,5-dimethylhexane 2,5-dihydroperoxide, and 1,1,3,3-tetramethylbutyl hydroperoxide; polyacyl peroxides of dibasic acids; polyperoxyesters of dibasic acids and polyols; and the like. These organic peroxides may be used alone or as a combination of two or more as a polymerization initiator. As long as the effects of the present invention are exhibited, there is no particular limitation to the blending amounts, but 0.001-5.0 parts by mass with respect to the total amount (100 parts by mass) of the above-mentioned raw material mixture is preferable.

In addition, chain transfer agents, antioxidants, etc. may be blended during the polymerization.

Examples of the chain transfer agents include mercaptans, α-methylstyrene linear dimers, monoterpenoid-based molecular weight modifiers (terpinolene), and the like. The foregoing may be used alone or as a combination of two or more.

Examples of the antioxidants include hindered phenols, hindered bisphenols, hindered trisphenols, and the like. Specifically, for example, 2,6-di-t-butyl-4-methylphenol, stearyl-β-(3,5-di-t-butyl-4-hydroxyphenyl) propionate, and the like may be used.

The copolymer resin according to the present invention may include additives such as antioxidants, inorganic stabilizers, ultraviolet absorbers, flame retardants, anti-static agents, colorants, fillers, organic polysiloxane, and the like as needed.

Examples of the antioxidants include the same antioxidants as those mentioned above.

Examples of the inorganic stabilizers include calcium, tin, and the like.

Examples of the ultraviolet absorbers include p-tert-butylphenylsalicylate, 2,2′-dihydroxy-4-methoxybenzophenohen, 2-(2′-hydroxy-4′-n-octoxyphenyl)benzothiazole, and the like.

Examples of the flame retardants include antimony oxide, aluminum hydroxide, zinc borate, tricresyl phosphate, chlorinated paraffin, tetrabromobutane, hexabromobutane, tetrabromobisphenol A, and the like.

Examples of the anti-static agents include stearamidopropyl dimethyl-3-hydroxyethyl ammonium nitrate, and the like.

Examples of the colorants include titanium dioxide, carbon black, and other inorganic or organic pigments.

Examples of the fillers include reinforcing elastomers such as calcium carbonate, clay, silica, glass fibers, glass balls, carbon fibers, methyl methacrylate-butadiene-styrene copolymers (MBS), styrene-butadiene-styrene copolymers (SBS), styrene-isoprene copolymers (SIS), or hydrogenated products thereof.

The above-mentioned additives may be used alone or as a combination of two or more. The above-mentioned additives may also be added during manufacturing.

The copolymer resin according to the present invention may contain plasticizers and lubricants as needed.

As the plasticizers, conventionally known plasticizers can be used, for example, such as phthalic acid-based plasticizers such as dibutylphthalate, dioctyl phthalate, diheptyl phthalate, butyl benzyl phthalate, and butylphthalylbutylglycolate; adipic acid-based plasticizers such as di-n-butyl adipate and di-(2-ethylhexyl adipate); citric acid-based plasticizers such as acetyl tri-n-butyl citrate; sebacic acid-based plasticizers such as di-n-butyl sebacate and di-(2-ethylhexyl) sebacate; epoxy-based plasticizers such as epoxidized soybean oil, epoxidized linseed oil, and epoxidized fatty acid esters; polyester-based plasticizers consisted of dibasic acids such as succinic acid, glutaric acid, and adipic acid, and a dihydric alcohol with a molecular weight of 200 or less such as ethylene glycol, 1,2-propylene glycol, 1,3-propylene glycol, 1,2-butylene glycol, 1,3-butylene glycol, and 1,4-butylene glycol; terpene-based resins and hydrogenated terpene-based resins; and the like. These plasticizers may be used alone or as a combination of two or more.

In addition, the copolymer resin according to the present invention may include monomers of the (meth)acrylic acid alkyl ester (x2). Including the monomers of the (x2) component as a plasticizer makes it easier to soften the resin sheet according to the present invention and to further improve the heat-sealing property at low temperatures. The above-mentioned monomers may be added to the copolymer resin or may be residual monomers at the time of manufacturing. When the copolymer resin includes the monomers of the (x2) component, the ratio thereof is preferably 700 ppm or less, more preferably 10-500 ppm, and still more preferably 20-300 ppm, with respect to the total mass of the copolymer resin. Note that when the above-mentioned monomer is a residual monomer at the time of manufacturing, the ratio of the residual monomers in the copolymer resin may be controlled within the above-mentioned range by adjusting the polymerization temperature, polymerization time, etc.

As the lubricants, conventionally known lubricants can be used, for example, such as metal soap-based and hydrocarbon-based liquid paraffin; polyethylene wax and the like; fatty acid-based higher fatty acid, hydroxy fatty acid, and the like; ester-based glyceride, ester wax, and the like; fatty acid amide-based fatty acid amide, bis-fatty acid amide, and the like; fatty acid ketone-based and compound lubricant-based lubricant; and the like. Specific examples thereof include paraffin wax, stearic acid, hardened oil, stearoylamide, ethylene bisstearamide, n-butyl stearate, ketone wax, octyl alcohol, lauryl alcohol, hydroxystearic triglyceride, polysiloxane, alkyl phosphates ester, and the like. These lubricants may be used alone or as a combination of two or more.

When plasticizers or lubricants are included, the added amount is preferably in the range of 0.05-1.0 parts by mass with respect to the total mass of the copolymer resin from the viewpoint of the processability of the resin sheet and the sealing property of the packaging container.

### [Method for Manufacturing Resin Sheet]

The resin sheet according to the present invention is composed of the above-mentioned copolymer resin. Conventionally known methods can be adopted as the method for manufacturing the resin sheet. Specifically, an example of the methods includes feeding the copolymer resin into an extruder and melt-kneading it, thereby creating resin pellets. These resin pellets are then fed into a sheet extruder such as a T-die and extruded to a desired thickness to form a resin sheet. Note that the resin sheet can be configured as a conductive resin sheet by forming a conductive layer on at least one surface thereof.

The resin sheet according to the present invention preferably has a thickness of 0.1 to 1 mm, and more preferably 0.15-0.8 mm from the viewpoint of the moldability and the strength of the packaging container.

### <Folding Endurance>

The resin sheet according to the present invention has excellent folding endurance. That is, the resin sheet according to the present invention has a folding endurance, measured in accordance with JIS-P-8115, of preferably 10 or more times, more preferably 30 or more times, and still more preferably 50 or more times. Note that the folding endurance of the resin sheet refers to a value measured under the following conditions.

### (Method for Measuring Folding Endurance)

In accordance with JIS-P-8115 (2001), a test piece with a length of 150 mm, a width of 15 mm, and a thickness of 0.3 mm is prepared with the flow direction of the resin sheet set the longitudinal direction thereof. An MIT folding strength is measured using an MIT folding endurance tester manufactured by Toyo Seiki Seisaku-sho, Ltd. At this time, the test is performed with a folding angle of 135°, a folding speed of 175 folds per minute, and a measurement load of 250 g.

### <Image Clarity>

The resin sheet according to the present invention has an image clarity, measured by an image clarity measuring device in accordance with JIS-K-7324, of preferably 60% or more, more preferably 70% or more, and still more preferably 75% or more. When the image clarity is 60% or higher, it is easier to view the electronic components accommodated in the pockets of the electronic component packaging containers. That is, a resin sheet that has such image clarity has excellent transparency.

### [Electronic Component Packaging Container]

By molding the resin sheet according to the present invention using known sheet molding methods (thermoforming) such as vacuum molding, pressure molding, and press molding, a free-form electronic component packaging container such as a carrier tape, a tray, etc. can be obtained. The resin sheet according to the present invention has transparency, excellent folding endurance, and also excellent low-temperature heat sealing property. Therefore, it is possible to provide an electronic component packaging container having these excellent properties.

### <Low-Temperature Heat Sealing Property>

The electronic component packaging container according to the present invention has an excellent heat sealing property. Specifically, the seal temperature at which the peel strength of a cover tape measured under the following conditions is 0.2 N or more, is preferably less than 165° C., more preferably less than 155° C., and still more preferably less than 145° C.

### (Method for Measuring Low-Temperature Heat Sealing Property)

Using a taping machine, a cover film with a 21.5 mm width is heat sealed to a carrier tape with a seal head width of 0.5 mm×2, a seal head length of 24 mm, a seal pressure of 0.5 kgf, a feed length of 12 mm, a seal period of 0.3 seconds, a seal iron temperature of 5° C. intervals from 140-190° C. Thereafter, the cover tape is peeled at a peeling rate of 300 mm per minute and a peeling angle of 170-180° at a temperature of 23° C. in an atmosphere with a relative humidity of 50%, and a seal temperature at which the peel strength is 0.2 N or more is confirmed.

### [Electronic Component Packaging Body]

An electronic component packaging container accommodates electric components, and thereby becomes an electronic component packaging body. This is used to store and transport electronic components. For example, carrier tapes are used for storing and transporting electronic components as carrier tape bodies. After being accommodated in a pocket formed by the above-mentioned molding method, the electric component is covered with a cover tape and then reeled up, thus becoming a carrier tape body. The resin sheet and the electronic component packaging container according to the present invention have excellent heat sealing properties at low temperatures. Therefore, the heat sealing temperature when forming an electronic component packaging body is preferably less than 165° C., more preferably 155° C. or less, and still more preferably 145° C. or less.

Another aspect of the present invention is a method for manufacturing an electronic component packaging body using an electronic component packaging container formed of a resin sheet composed of the above-mentioned copolymer resin, the method including heat sealing a lid material to the above-mentioned electronic component packaging container at a heat sealing temperature of less than 165° C., and preferably 155° C. or less.

Electronic components packaged in electronic component packaging bodies are, for example, but not specifically limited to, ICs, LEDs (light emitting diodes), resistors, liquid crystals, capacitors, transistors, piezoelectric element resistors, filters, crystal oscillators, crystal resonators, diodes, connectors, switches, volumes, relays, inductors, and the like. The electronic components packaged in electronic component packaging bodies may also be intermediate or final products that use these electronic components.

More preferable aspects of the resin sheet according to the present invention are as follows.

[1] A resin sheet for electronic component packaging, the resin sheet composed of a rubber-modified aromatic vinyl-based copolymer resin that contains rubber-type polymers (Y) as dispersed particles in a continuous matrix resin (X), and that satisfies (1) and (2) below:
(1) the continuous matrix resin (X) is a copolymer of 53-63 mass % of styrene, and 37-47 mass % of a (meth)acrylic acid alkyl ester including methyl methacrylate and butyl acrylate; and
(2) the ratio of the rubber-type polymers (Y) with respect to the total mass of the rubber-modified aromatic vinyl-based copolymer resin is 5 mass % or more and less than 10 mass %.

[2] The resin sheet for electronic component packaging of [1], wherein the ratio of the methyl methacrylate with respect to the butyl acrylate (methyl methacrylate/butyl acrylate) is 4 to 6.

[3] The resin sheet for electronic component packaging of [1] or [2], wherein the resin sheet further satisfies (3) or (4) described below:
(3) the ratio of styrene to the rubber-modified aromatic vinyl-based copolymer resin is 49.5-55.0 mass %; and
(4) the ratio of the total amount of the methyl methacrylate and butyl acrylate to the rubber-modified aromatic vinyl-based copolymer resin is 35-44 mass %.

[4] The resin sheet for electronic component packaging of any one of [1] to [3], wherein the amount of at least one monomer selected from the methyl methacrylate and butyl acrylate included in the rubber-modified aromatic vinyl-based copolymer resin is 700 ppm or less with respect to the total mass of the rubber-modified aromatic vinyl-based copolymer resin.

[5] An electronic component packaging container formed using the resin sheet for electronic component packaging of any one of [1] to [4].

[6] An electronic component packaging body including the electronic component packaging container of [5].

[7] A method for manufacturing the electronic component packaging body of [6], the method including sealing a lid material to the electronic component packaging container at a heat sealing temperature of less than 165° C.

### EXAMPLES

Hereinafter, the present invention shall be explained in more detail by providing examples, but the present invention is not limited by the descriptions below.

### [Creating Resin Sheet for Electronic Component Packaging]

### Example 1

100 parts by mass of a solution in which 7.5 parts by mass of a styrene-butadiene block copolymer rubber (manufactured by Asahi Kasei Corporation; product name: “ASAPRENE 670A”; styrene concentration: 39 mass %) was dissolved with 45.0 parts by mass of a styrene monomer, 34.0 parts by mass of methyl methacrylate, 5.0 parts by mass of butyl acrylate, and 8.5 parts by mass of ethylbenzene was further blended with a solution in which 0.005 parts by mass of 1,1-bis(t-butylperoxy)3,3,5-trimethylcyclohexane and 0.08 parts by mass of t-dodecyl mercaptan were blended, and the obtained reaction solution was continuously fed into a first polymerization machine and was stirred and polymerized for three hours at a polymerization temperature of 125° C. Thereafter, the above-mentioned obtained reaction solution was continuously charged in full amount into a plug flow-type reactor such that the retention time thereof is five hours, and was further polymerized. After being polymerized until the polymerization ratio reached 85%, the polymerized reaction liquid was fed into a vent-type extruder to remove volatile components at 230° C. under reduced pressure. Moreover, molten strands were drawn out from a die and water-cooled, and then cut with a cutter to obtain a pellet-shaped rubber-modified aromatic vinyl copolymer resin.

Then the obtained copolymer resin was fed into a T-die sheet extruder and molded to a thickness of 0.3 mm and a width of 600 mm to obtain a resin sheet. Note that the remaining monomer amount of the (x2) component in the obtained resin sheet was 280 ppm.

The obtained resin sheet was slit into widths of 24 mm and molded using a pressure molding machine at a heating temperature condition of 210° C., thereby creating a carrier tape with a width of 24 mm. The pocket size of the carrier tape is 15 mm in the flow direction, 11 mm in the width direction, and 5 mm in the depth direction. Using the obtained resin sheet and carrier tape, the folding endurance, the image clarity, and the low-temperature heat sealing property were evaluated under the following conditions. The results are shown in Table 1. Note that the blending ratio (mass %) of the (Y) component in Table 1 is a value calculated from the following formula (3).

$$[ ( Y ) / ( X + Y ) ] \times 100 \qquad ( 3 )$$

In formula (3), Y is the total preparation amount of all of the rubber-type polymers (Y), and X is a value obtained by multiplying a polymerization rate (%) by the total preparation amount of all of the monomers constituting the (X) component.

### (Folding Endurance)

In accordance with JIS-P-8115 (2001), a test piece with a length of 150 mm, a width of 15 mm, and a thickness of 0.3 mm was prepared by setting the flow direction of the resin sheet as a longitudinal direction. Then the MIT folding endurance was measured using an MIT folding endurance tester (product name: “MIT-D”) manufactured by Toyo Seiki Seisaku-sho, Ltd. At this time, the test was performed with a folding angle of 135°, a folding speed of 175 folds per minute, and a measurement load of 250 g. Moreover, folding endurance was evaluated in accordance with the following evaluation criteria, and a “B rating” or higher was considered to be a pass.

### (Evaluation Criteria)

A: Folding endurance of 30 times or more.
B: Folding endurance of 10 times or more and less than 30 times.
C: Folding endurance of less than 10 times.

### (Image Clarity)

The image clarity of the resin sheet was measured in accordance with JIS-K-7374 using an image clarity measuring device. Moreover, the image clarity was evaluated in accordance with the following evaluation criteria, and a “B rating” or higher was considered to be a pass (excellent transparency).

### (Evaluation Standard)

A: Image clarity is 70% or more and 100% or less.
B: Image clarity is 60% or more and less than 70%.
C: Image clarity is less than 60%.

### (Low-Temperature Heat Sealing Property)

Using a taping machine (manufactured by NAGATA SEIKI CO., LTD.; product name: “NK-600”), a 21.5 mm width cover tape (manufactured by Denka Company Limited; product name: “ALS-S”) was heat sealed to a carrier tape with a seal head width of 0.5 mm×2, a seal head length of 24 mm, a seal pressure of 0.5 kgf, a feed length of 12 mm, a seal period of 0.3 seconds, a seal iron temperature of 5° C. intervals from 140° C. to 190° C. Thereafter, the cover tape was peeled at a peeling rate of 300 mm per minute and a peeling angle of 170-180° at a temperature of 23° C. in an atmosphere with a relative humidity of 50%, and thus the low-temperature sealing property was evaluated. The evaluation was performed in accordance with the following evaluation criteria, and a “B rating” or higher was considered to be a pass (excellent low-temperature heat sealing property).

### (Evaluation Standard)

A: Temperature at which peel strength reaches 0.2 N or more is less than 155° C.
B: Temperature at which peel strength reaches 0.2 N or more is 155° C. or more and less than 165° C.
C: Temperature at which peel strength reaches 0.2 N or more is 165° C. or more.

### Examples 2 to 10 and Comparative Examples 1 to 3

Except for setting the blending ratio of each component as shown in Table 1, the same operations as in Example 1 were performed to obtain resin sheets and carrier tapes. The obtained resin sheets and carrier tapes were evaluated with regard to their folding endurance, image clarity, and low-temperature heat sealing property by the same method as in Example 1. The results are shown in Table 1.

The details of the raw materials shown in Table 1 are as follows.
Rubber 1: Styrene-butadiene block copolymer rubber (manufactured by Asahi Kasei Corporation; product name: “ASAPRENE 670A”; styrene concentration: 39 mass %).
Rubber 2: Styrene-butadiene block copolymer rubber (manufactured by Asahi Kasei Corporation; product name: “ASAPRENE 625A”; styrene concentration: 35 mass %).
Rubber 3: Styrene-butadiene block copolymer rubber (manufactured by Asahi Kasei Corporation; product name: “ASAPRENE 610A”; styrene concentration: 15 mass %).

TABLE 1

| | | | | | Exam- | Exam- | Exam- | Exam- | Exam- | Exam- | Exam- |
|---|---|---|---|---|---|---|---|---|---|---|---|
| | | | | | ple | ple | ple | ple | ple | ple | ple |
| | | | | | 1 | 2 | 3 | 4 | 5 | 6 | 7 |
| Rubber- | Rubber 1 | | | (Parts | 7.5 | | | 4.0 | 7.5 | 7.5 | 7.5 |
| type | Rubber 2 | | | by | | 7.5 | | | | | |
| polymer | Rubber 3 | | | mass) | | | 7.5 | | | | |
| (Y) | | | | | | | | | | | |
| Continuous | (×1) component | | Styrene | | 45.0 | 46.0 | 45.0 | 47.5 | 52.5 | 45.0 | 45.0 |
| matrix | (×2) | (×2-1) | Methyl | | 34.0 | 33.0 | 19.5 | 25.0 | 20.0 | 37.0 | 34.0 |
| resin | compo- | | meth- | | | | | | | | |
| (X) | nent | | acrylate | | | | | | | | |

| | | | | | | | | |
|---|---|---|---|---|---|---|---|---|
| (×2-2) | Butyl | 5.0 | 5.0 | 19.5 | 15.0 | 11.5 | 2.0 | |
| | acrylate | | | | | | | |
| | Acrylic | | | | | | | 5.0 |
| | acid | | | | | | | |
| | 2-ethyl- | | | | | | | |
| | hexyl | | | | | | | |

Lauryl
acrylate

| Organic solvent | | Ethylbenzene | | 8.5 | 8.5 | 8.5 | 8.5 | 8.5 | 8.5 | 8.5 |
|---|---|---|---|---|---|---|---|---|---|---|
| Total preparation | | | (Parts | 100 | 100 | 100 | 100 | 100 | 100 | 100 |
| amount | | | by | | | | | | | |
| | | | mass) | | | | | | | |
| Polymerization rate | | | (%) | 85 | 85 | 85 | 85 | 85 | 85 | 85 |
| Blend- | (Y) | Ratio of (Y) | (mass %) | 9.5 | 9.5 | 9.5 | 6.1 | 9.5 | 9.5 | 9.5 |
| ing | compo- | component | | | | | | | | |
| ratio | nent | ((Y)/(X + Y)) | | | | | | | | |
| | (X) | (Ratio of (×1) | | 53.8 | 54.8 | 53.6 | 54.3 | 62.5 | 53.8 | 53.8 |
| | compo- | component | | | | | | | | |
| | nent | ((×1)/(X)) | | | | | | | | |
| | | (Ratio of (×2) | | 46.4 | 45.2 | 45.4 | 45.7 | 37.5 | 46.4 | 46.4 |
| | | component | | | | | | | | |
| | | (×2)/(X)) | | | | | | | | |
| | | (×2-2) component/ | | 12.8 | 13.2 | 50.0 | 37.5 | 36.5 | 5.1 | 12.8 |
| | | (×2) component | | | | | | | | |

| Physical | Folding | Mea- | (times) | 65 | 61 | 48 | 41 | 54 | 52 | 68 |
|---|---|---|---|---|---|---|---|---|---|---|
| property | endur- | surement | | | | | | | | |
| eval- | ance | result | | | | | | | | |
| uation | | Eval- | (—) | A | A | A | A | A | A | A |

| | uation | | | | | | | | |
|---|---|---|---|---|---|---|---|---|---|
| | result | | | | | | | | |
| Image | Mea- | (%) | 85 | 92 | 52 | 85 | 78 | 90 | 84 |
| Clarity | surement | | | | | | | | |
| | result | | | | | | | | |
| | Eval- | (—) | A | A | B | A | A | A | A |
| | uation | | | | | | | | |
| | result | | | | | | | | |
| Low- | Temper- | (° C.) | 145 | 145 | 150 | 150 | 145 | 150 | 150 |
| temper- | ature | | | | | | | | |
| ature | at which | | | | | | | | |
| heat | 0.2N or | | | | | | | | |
| sealing | more is | | | | | | | | |
| property | reached | | | | | | | | |

| | | | | | | | | |
|---|---|---|---|---|---|---|---|---|
| Eval- | (—) | A | A | A | A | A | A | A |
| uation | | | | | | | | |
| result | | | | | | | | |

| | | | | | | | | Compar- | Compar- | Compar- |
|---|---|---|---|---|---|---|---|---|---|---|
| | | | | | | | | ative | ative | ative |
| | | | | | Exam- | Exam- | Exam- | Exam- | Exam- | Exam- |
| | | | | | ple | ple | ple | ple | ple | ple |
| | | | | | 8 | 9 | 10 | 1 | 2 | 3 |
| Rubber- | Rubber 1 | | | (Parts | 7.5 | 7.6 | 7.5 | 7.5 | 2.5 | 10 |
| type | Rubber 2 | | | by | | | | | | |
| polymer | Rubber 3 | | | mass) | | | | | | |
| (Y) | | | | | | | | | | |
| Continuous | (×1) component | | Styrene | | 45.0 | 45.0 | 48.5 | 42.0 | 47.7 | 43.7 |
| matrix | (×2) | (×2-1) | Methyl | | 34.0 | 38.0 | 17.0 | 37.0 | 36.0 | 33.0 |
| resin | compo- | | meth- | | | | | | | |
| (X) | nent | | acrylate | | | | | | | |

| | | | | | | |
|---|---|---|---|---|---|---|
| (×2-2) | Butyl | 1.0 | 20.5 | 5.0 | 5.3 | 4.5 |
| | acrylate | | | | | |
| | Acrylic | | | | | |
| | acid | | | | | |
| | 2-ethyl- | | | | | |
| | hexyl | | | | | |

| | |
|---|---|
| Lauryl | 5.0 |
| acrylate | |

| Organic solvent | | Ethylbenzene | | 8.5 | 8.5 | 8.5 | 8.5 | 8.5 | 8.5 |
|---|---|---|---|---|---|---|---|---|---|
| Total preparation | | | (Parts | 100 | 100 | 100 | 100 | 100 | 100 |
| amount | | | by | | | | | | |
| | | | mass) | | | | | | |
| Polymerization rate | | | (%) | 85 | 85 | 85 | 85 | 85 | 85 |
| Blend- | (Y) | Ratio of (Y) | (mass %) | 9.5 | 9.5 | 6.5 | 9.5 | 3.2 | 12.6 |
| ing | compo- | component | | | | | | | |
| ratio | nent | ((Y)/(X + Y)) | | | | | | | |
| | (X) | (Ratio of (×1) | | 53.6 | 53.8 | 55.4 | 50.0 | 53.8 | 53.8 |
| | compo- | component | | | | | | | |
| | nent | ((×1)/(X)) | | | | | | | |
| | | (Ratio of (×2) | | 46.4 | 46.4 | 44.6 | 50.0 | 46.4 | 45.4 |
| | | component | | | | | | | |
| | | (×2)/(X)) | | | | | | | |
| | | (×2-2) component/ | | 0.0 | 2.5 | 54.7 | 11.9 | 12.8 | 12.7 |
| | | (×2) component | | | | | | | |

| Physical | Folding | Mea- | (times) | 72 | 64 | 41 | 58 | 7 | 71 |
|---|---|---|---|---|---|---|---|---|---|
| property | endur- | surement | | | | | | | |
| eval- | ance | result | | | | | | | |
| uation | | Eval- | (—) | A | A | A | A | C | A |

| | uation | | | | | | | |
|---|---|---|---|---|---|---|---|---|
| | result | | | | | | | |
| Image | Mea- | (%) | 86 | 92 | 68 | 72 | 91 | 69 |
| Clarity | surement | | | | | | | |
| | result | | | | | | | |
| | Eval- | (—) | A | A | B | A | A | B |
| | uation | | | | | | | |
| | result | | | | | | | |
| Low- | Temper- | (° C.) | 160 | 155 | 155 | 165 | 145 | 165 |
| temper- | ature | | | | | | | |
| ature | at which | | | | | | | |
| heat | 0.2N or | | | | | | | |
| sealing | more is | | | | | | | |
| property | reached | | | | | | | |

| | | | | | | | |
|---|---|---|---|---|---|---|---|
| Eval- | (—) | B | B | B | C | A | C |
| uation | | | | | | | |
| result | | | | | | | |

As shown in Table 1, the resin sheets for electronic component packaging of Examples 1 to 10 satisfying the composition of the present invention had transparency, excellent folding endurance, and also excellent low-temperature heat sealing properties. Meanwhile, the resin sheet of Comparative Example 1, in which the ratios of the (x1) component and the (x2) component in the (X) component do not satisfy the composition of the present invention, had a high heat sealing temperature of 165° C. The resin sheet of Comparative Example 2, in which the blending amount of the rubber-type polymers (Y) was less than 5 mass %, had a low folding endurance. In addition, the resin sheet of Comparative Example 3, in which the blending amount of the rubber-type polymers (Y) was more than 10 mass %, had a high heat sealing temperature of 165° C. Moreover, the resin sheet of Comparative Example 3 had a slightly inferior image clarity. From the above results, it was confirmed that the resin sheet for electronic component packaging according to the present invention has transparency, excellent folding endurance, and also excellent low-temperature heat sealing property.

1. A resin sheet for electronic component packaging, the resin sheet composed of a rubber-modified aromatic vinyl-based copolymer resin that includes rubber-type polymers (Y) as dispersed particles in a continuous matrix resin (X) and that satisfies (1) and (2) below:
(1) the continuous matrix resin (X) is a copolymer of 53-63 mass % of one or more aromatic vinyl-based compounds (x1) and 37-47 mass % of one or more (meth)acrylic acid alkyl esters (x2); and
(2) a ratio of the rubber-type polymers (Y) to the total mass of the rubber-modified aromatic vinyl-based copolymer resin is 5 mass % or more and less than 10 mass %.

2. The resin sheet for electronic component packaging according to claim 1, wherein the (meth)acrylic acid alkyl ester (x2) comprises methyl methacrylate (x2-1), and a (meth)acrylic acid alkyl ester (x2-2) having a linear or branched alkyl group with 4-8 carbon atoms.

3. The resin sheet for electronic component packaging according to claim 2, wherein a ratio of the (meth)acrylic acid alkyl ester (x2-2) to the total mass of the (meth)acrylic acid alkyl ester (x2) is 5-50 mass %.

4. The resin sheet for electronic component packaging according to claim 2, wherein the (meth)acrylic acid alkyl ester (x2-2) comprises butyl acrylate.

5. An electronic component packaging container formed using the resin sheet for electronic component packaging according to claim 1.

6. The electronic component packaging container according to claim 5, wherein the electronic component packaging container is a carrier tape.

7. The electronic component packaging container according to claim 5, wherein the electronic component packaging container is a tray.

8. An electronic component packaging body comprising the electronic component packaging container according to claim 5.

9. The resin sheet for electronic component packaging according to claim 3, wherein the (meth)acrylic acid alkyl ester (x2-2) comprises butyl acrylate.

10. An electronic component packaging container formed using the resin sheet for electronic component packaging according to claim 2.

11. An electronic component packaging container formed using the resin sheet for electronic component packaging according to claim 3.

12. An electronic component packaging container formed using the resin sheet for electronic component packaging according to claim 4.

13. An electronic component packaging body comprising the electronic component packaging container according to claim 6.

14. An electronic component packaging body comprising the electronic component packaging container according to claim 7.
